(19) United States
(12) Patent Application Publication
(10) Pub. No.: US 2019/0357375 A1
(43) Pub. Date: Nov. 21, 2019

(54) ADJUSTABLE ASSEMBLY AND TEST MEDIA TRAY

(71) Applicant: Intel Corporation, Santa Clara, CA (US)

(72) Inventors: Garrett WYATT, Mesa, AZ (US); Nathan HECKATHORNE, Chandler, AZ (US)

(21) Appl. No.: 15/985,568

(22) Filed: May 21, 2018

(51) Int. Cl. H05K 7/14; H05K 7/18

(52) U.S. Cl. CPC H05K 7/1422; H05K 7/18; H05K 7/1405

(57) ABSTRACT

An assembly and test tray includes a tray frame and at least one column movably coupled to the tray frame. At least one pocket component is movably coupled to the column.

### TECHNICAL FIELD

Embodiments of the disclosure are in the field of assembly and test media trays and, in particular, adjustable assembly and test media trays.

### BACKGROUND

The assembly of microprocessors requires the use of assembly and test media trays for conveyance through the various steps of the microprocessor assemblage and testing process. In one approach, a custom designed plastic injection molded tray is required that is limited to use for a specific form factor. Any deviation in form factor precludes reuse opportunities (with trays having other form factors) and requires a new tray design. Tray designs are very costly, and require an eight week lead time for delivery of parts. Some companies place orders for hundreds of thousands of trays per year for various types of trays at a cost of millions of dollars. The cost of tooling will continue to rise for companies that have tray sourcing needs that are based on both high product mix tray orders as well as special low volume tray orders. Not only does this create financial challenges, but vendor sourcing challenges as well, because the business model of vendors generally is not designed to accommodate such needs.

Because of the magnitude of the number of the various form factors used, and the fact that many products require a plurality of trays to effectively assemble and test, companies can spend a great deal of time and resources designing assembly and test trays, purchasing necessary injection molding tooling, purchasing individual piece parts, and managing increasing numbers of tray parts and fully formed trays. In conventional approaches, products or test vehicles can be low volume runners and yet incur the same tooling costs as high volume products. Moreover, variations in form factor as small as 0.5 mm, which is common, require all new media and tooling.

### BRIEF DESCRIPTION OF THE DRAWINGS

FIG. 1 is an illustration of a conventional assembly and test tray.

FIG. 2 is an illustration of a perspective view of the conventional assembly and test tray of FIG. 1.

FIG. 3 is an illustration of the conventional assembly and test tray of FIG. 1 with packages.

FIG. 4A is an illustration of a fully assembled assembly and test tray according to an embodiment.

FIG. 4B is an illustration of the open space of the tray frame of FIG. 4A and the tracks and interlocking structures that border the open space according to an embodiment.

FIG. 4C is an illustration of a perspective view of the open space of the tray frame shown in FIG. 4B that shows a part of the tray frame that extends below the surface of the tray frame according to an embodiment.

FIG. 4D shows a close-up view of a system of components that enable the coupling of the columns to the tray frame and the position of the columns to be adjusted in an incremental manner according to an embodiment.

FIG. 4E is an illustration of a movable column such as that shown in FIG. 4A according to an embodiment.

FIG. 4F is an illustration that shows details of a movable column according to an embodiment.

FIG. 4G is an illustration that shows a perspective view of a movable magnetic pocket component of an embodiment.

FIG. 4H is an illustration of an assemblage of a movable magnetic pocket component and a column according to an embodiment.

FIG. 4I is an illustration that shows another perspective view of an assemblage of a movable magnetic pocket component and a column according to an embodiment.

FIG. 4J is an illustration that shows another perspective view of an assemblage of a movable magnetic pocket component and a column according to an embodiment.

FIG. 4K is an illustration that shows another perspective view of an assemblage of a movable magnetic pocket component and a column according to an embodiment.

FIG. 4L is an illustration of an example pocket configuration according to an embodiment.

FIG. 5 is an illustration of a tray such as shown in FIG. 4A reconfigured to accommodate packages of a different size than the packages of FIG. 4A according to an embodiment.

FIG. 6 is a schematic of a computer system, in accordance with an embodiment of the present invention.

### DESCRIPTION OF THE EMBODIMENTS

Adjustable assembly and test media trays are disclosed. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

An embodiment provides a fully adjustable assembly and test media tray (hereinafter “tray”) that can accommodate various package form factors as well as tray densities. This is accomplished using a small set of standardized and discrete tray components that can be easily assembled, accurately placed, and reused. In an embodiment, the tray components can be adjusted to accommodate the dimensions of semiconductor packages (hereinafter “packages”) having a wide range of form factors.

Embodiments lower the number of trays that need to be ordered, reduce lead time (the standard eight week lead time to manufacture trays), and save on tooling costs by enabling an increase in size, decrease in size, and/or adjustment of the position of the pockets that hold packages. Embodiments use custom stepping, geometrical locking structures, clipping structures, and magnetized structures. Embodiments enable reduced inventories (the number of trays that need to be stored and tracked), and money savings in both engineering labor and material costs.

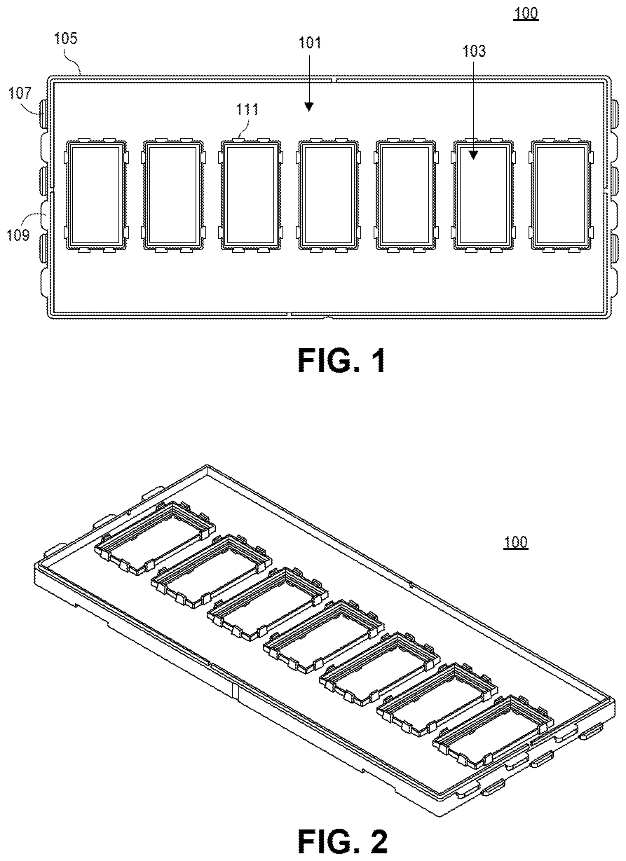

FIG. 1 is an illustration of a conventional assembly and test media tray 100. FIG. 1 shows tray frame 101, tray pockets 103, tray sidewalls 105, upper tabs 107, lower tabs 109, and clamps 111. The assembly and test media tray 100 is created from a mold and is a nonadjustable structure. Because assembly and test media tray 100 is nonadjustable, it is only suitable for packages having dimensions of the package for which it is created. For example, standard JEDEC assembly and test media trays, such as that shown in FIG. 1, are valid for form factors of 31 mm×58.5 mm and cannot be used for form factors that have different dimensions. FIG. 2 is an illustration that shows a view of FIG. 1 that provides additional details of the structures shown in FIG. 1.

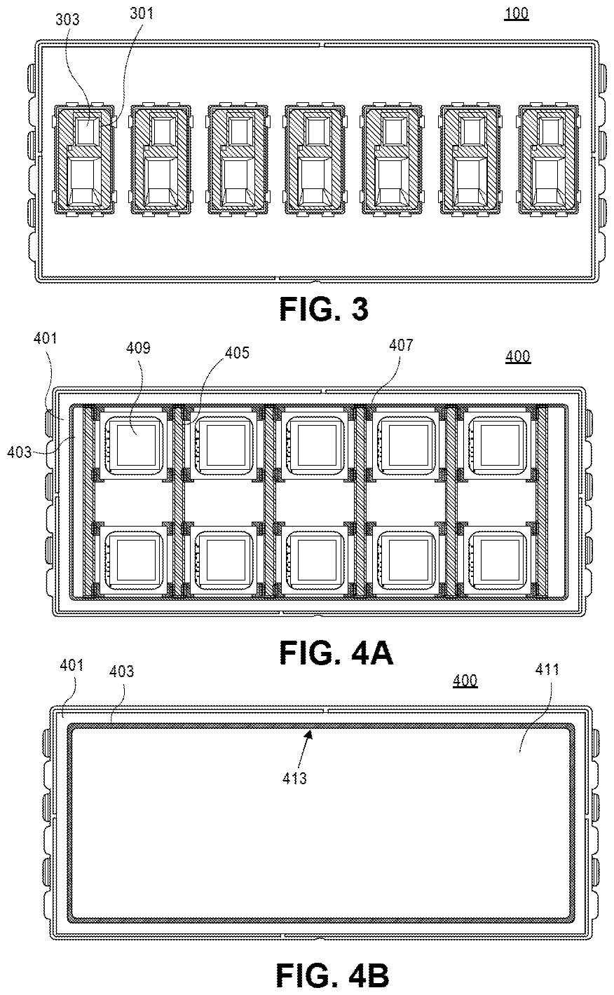

FIG. 3 is an illustration of the assembly and test media tray of FIG. 1 populated with semiconductor packages 301. In FIG. 3, the semiconductor packages 301 are shown as being encapsulated in cases 303. The cases 303 can prevent physical damage to encapsulated semiconductor material inside the semiconductor packages 301.

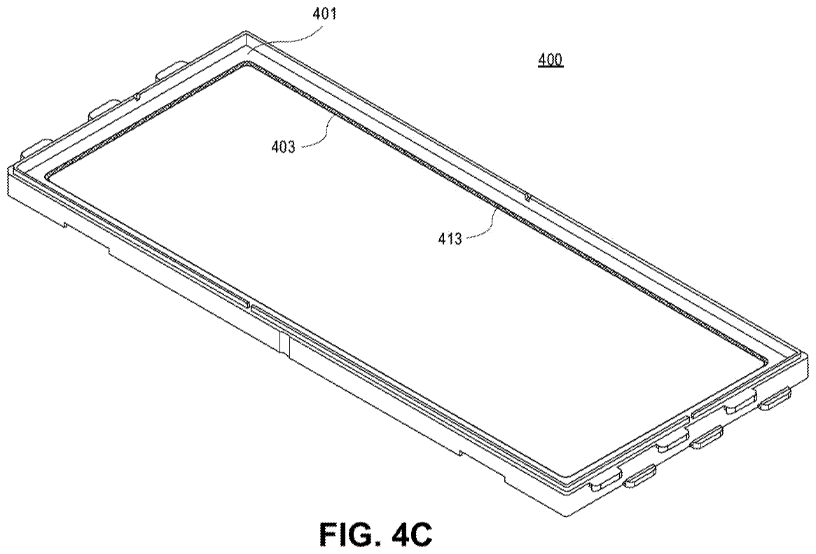

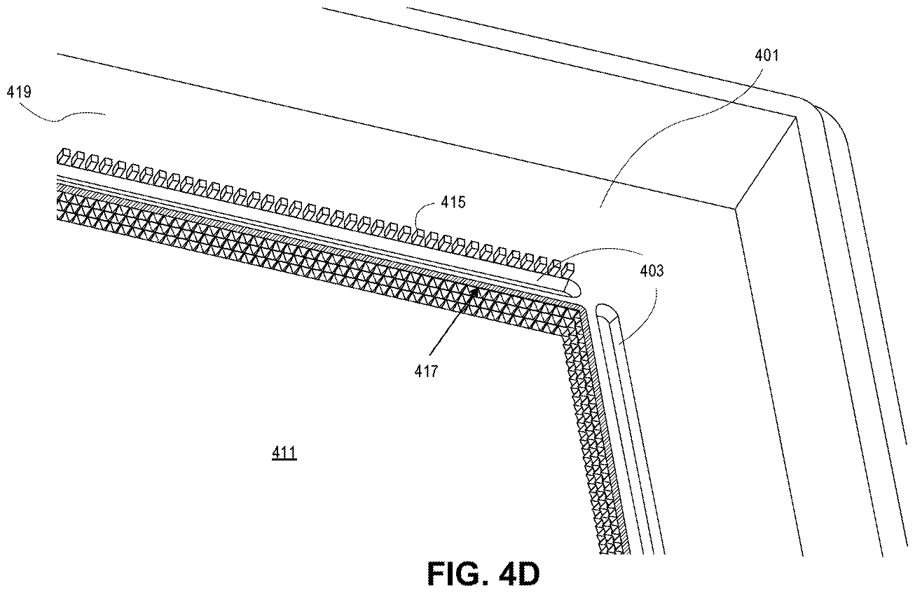

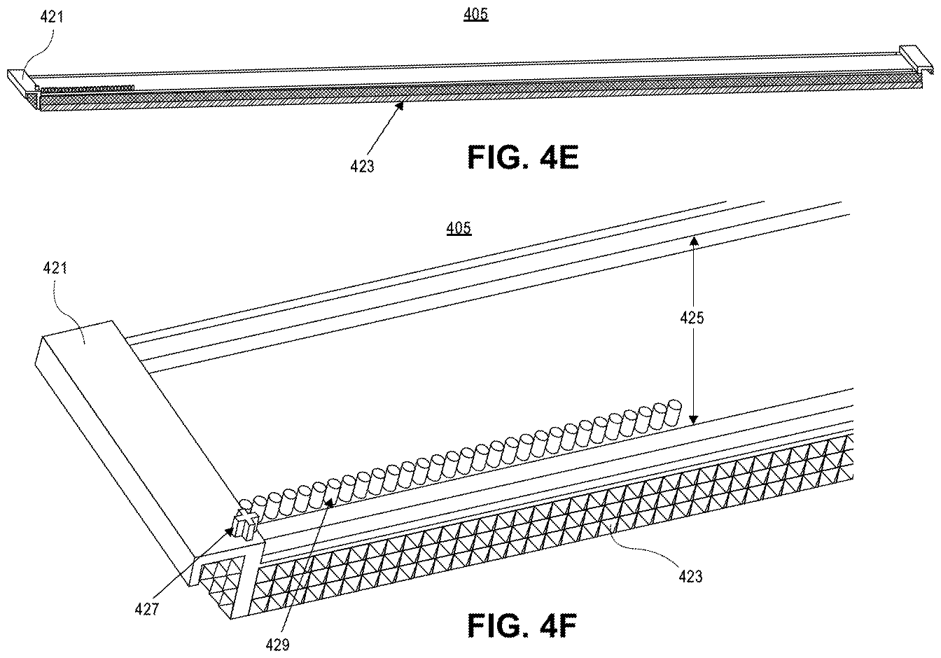

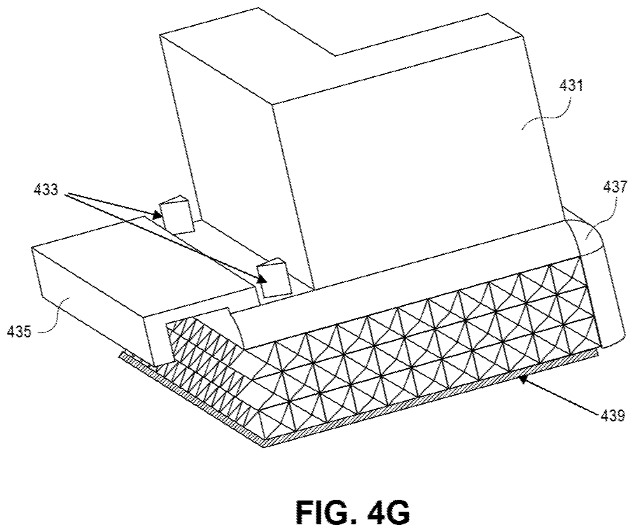

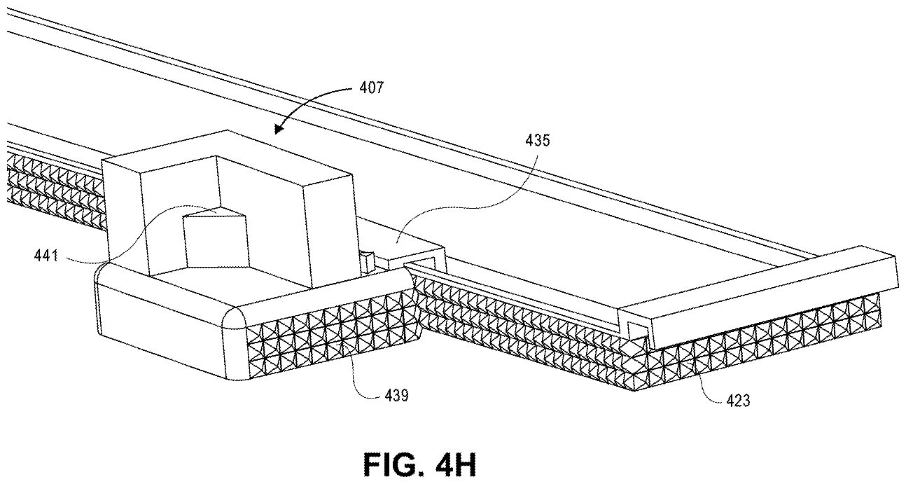

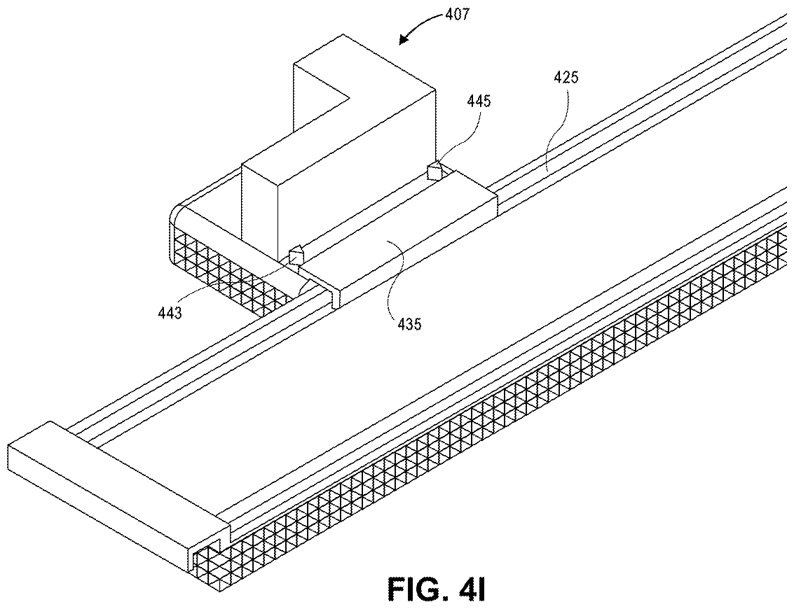

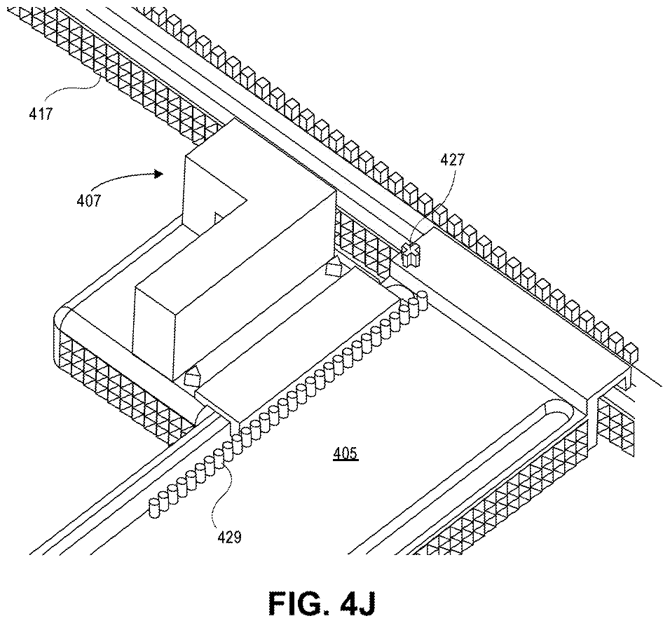

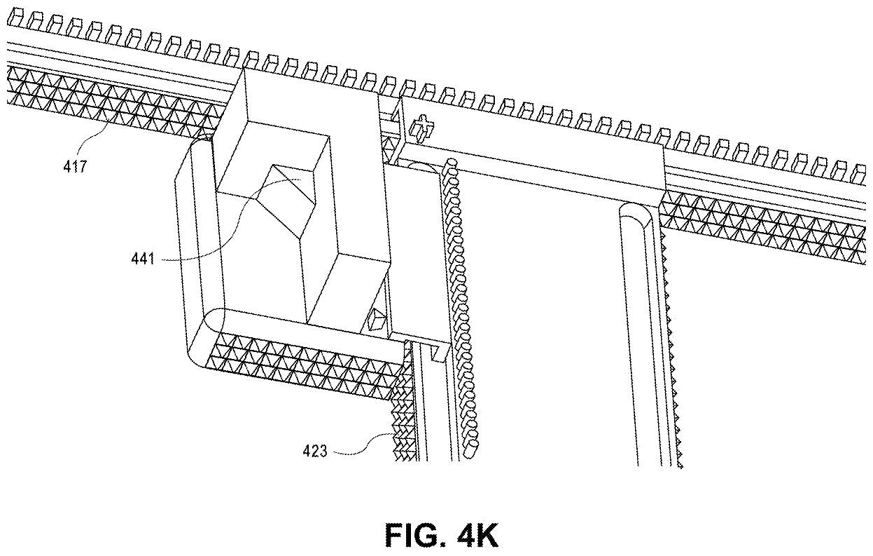

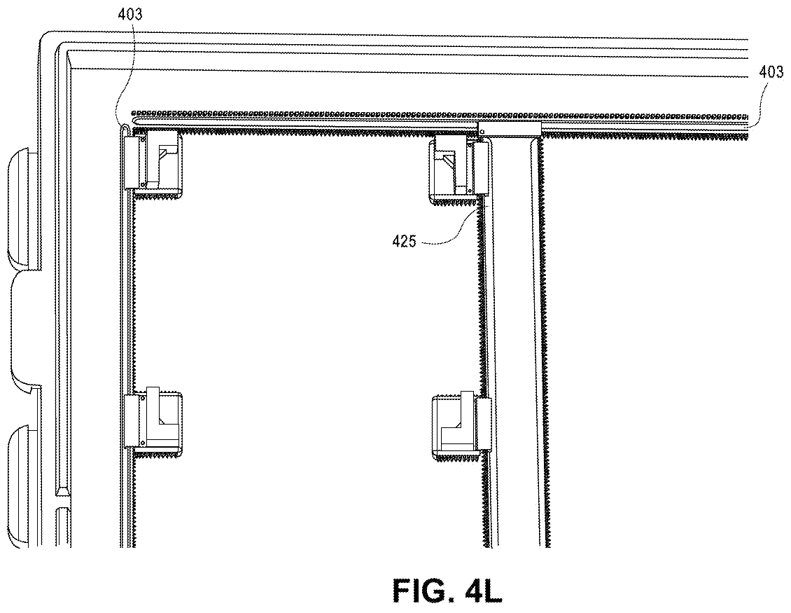

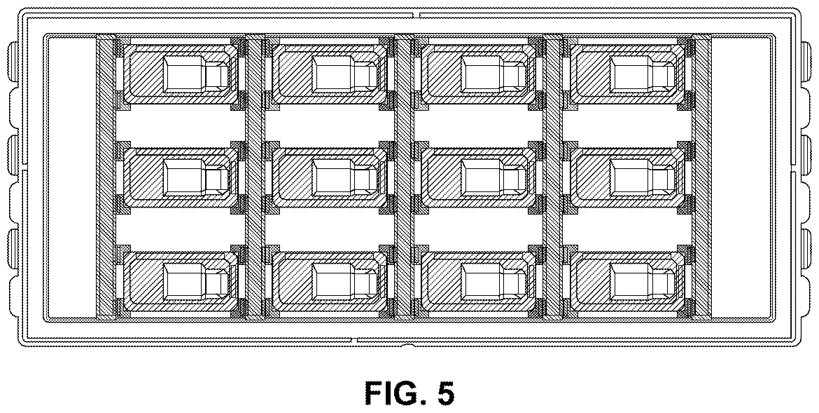

FIG. 4A is an illustration of a fully assembled assembly and test media tray 400 according to an embodiment. In the FIG. 4A embodiment, assembly and test media tray 400 includes tray frame 401, tracks 403, movable columns 405, movable pocket components 407 and semiconductor packages 409. These components of assembly and test media tray 400 are described below with reference to FIGS. 4B-4L.

Referring to FIG. 4B tray 400, in contrast to the conventional tray 100 of FIG. 3, includes an open space 411 that is bordered by the tracks 403 and interlocking structures 413. FIG. 4C is an illustration of a perspective view of the open space 411 of the tray frame shown in FIG. 4B that shows the part of the tray frame that extends below the surface of the tray frame according to an embodiment. This part of the tray frame 401 includes the interlocking structures 413 that are a part of a system of components that enable the adjustment of columns (405 in FIG. 4A). The interlocking structures control the adjustment of the columns 405 by enabling a locking of the columns 405 at increments that correspond to the size of the interlocking structures 413. In an embodiment, because the positions of the magnetized interlocking structures are known, the magnetized interlocking structures 413 on the perimeter of the open space 411 of the tray frame 401 facilitate the positioning of the columns 405 in the tray 400 as needed.

FIG. 4D shows a close-up view of a system of components that enable the precise placement, and incremental adjustment of the position of columns (405 in FIG. 4A) with respect to the tray frame 401. FIG. 4D shows tracks 403, fiducials 415 (for pick and place accuracy), and magnetized intelocking structures 417. Referring to FIG. 4D, the tracks 403 are formed in the top surface 419 of the tray frame 401 on each side of the open space 411 that is formed in the center of the tray 400. In FIG. 4D, the fiducials 415 are shown as being formed on the outside of, and adjacent to, the tracks 403 to assist in the placement of movable columns (405 in FIG. 4A). Moreover, in FIG. 4D, the interlocking structures 417 are shown as being formed below the tray frame surface 419 to the inside of the tracks 403. In an embodiment, the fiducials 415 enable the accurate clipping of movable columns (405 in FIG. 4A) into place through pick and place automation. In other embodiments, movable columns can be placed by any other suitable manner of placing the movable columns.

Referring again to FIG. 4A, based on the fiducials 415 shown in FIG. 4D, the movable columns 405 are coupled to the tracks 403 that are located on a first and a second side of tray frame 401. FIG. 4E shows a movable column 405 such as are shown in FIG. 4A. The movable column 405 includes a clip 421 that is inserted into the tracks 403 of the tray frame 401 and that adjustably couples the movable column 405 to the tray frame 401. In addition, the clip 421 includes magnetized interlocking structures 423 that are configured to engage magnetized interlocking structures on a movably coupled pocket component (407 in FIG. 4A) that can be clipped thereto. FIG. 4F shows additional details of the movable column 405. As shown in FIG. 4F, the movable column 405 includes tracks 425 that are configured to accommodate clip portions of the movable pocket components (407 in FIG. 4A) that movably couple the movable pocket components (407 in FIG. 4A) to the movable column 405. In addition, the movable column 405 includes fiducial structures 427 and 429. The fiducial structure 427 enables the precise placement of the movable column onto the tray (e.g., 400 in FIG. 4A). The fiducial structures 429 enable the precise placement of movable pocket components (e.g., 407 in FIG. 4A) onto the movable columns 405. Also, the movable column 405 includes magnetic interlocking structures 423 on its side, and anterior and posterior parts. The magnetic interlocking structures 423 located on the sides of the movable column 405 are configured to engage magnetic interlocking structures (as described in detail herein with reference to FIG. 4G) that are located on the base of movable pocket components (e.g., 407 in FIG. 4A).

In an embodiment, the magnetized interlocking structures 423 enable the movable column 405 to be movably positioned anywhere along the perimeter of the open space in the center of the tray frame (e.g., 401 in FIG. 4A). This capability enables customizable column positioning such that the location of one or more columns of a tray can be adjusted to accommodate form factors different from those that the tray was configured to accommodate initially thus enabling a tray to be reused based on a reconfiguration of the tray (e.g., 400 in FIG. 4A).

Referring to FIG. 4A, the movable pocket components 407 are used to secure packages 409 in the tray frame 401. For example, as shown in FIG. 4A, sets of four movable pocket components 407 are adjusted to form spaces that accommodate the packages 409. In particular, in an embodiment, the sets of movable pocket components 407 can be adjusted to form spaces that match the space requirements of the form factors of packages to be secured therein.

FIG. 4G shows a perspective view of a movable pocket component 407 of an embodiment. In an embodiment, the parts of the movable pocket component 407 include pocket structure 431, fiducials 433, clip structure 435, base structure 437 and magnetized interlocking structures 439. Sets of movable pocket components 407 can be used to create a customizable pocket space that is used to accommodate packages that have various dimensions. The movable pocket component 407 can be clipped onto a column or a tray by inserting the clip structure 435 into a track of the column or tray whereupon the movable pocket component is movably/adjustably attached thereto. The set of movable pocket components that are used to create the customimzable pocket space can be indexed (moved to a specific position) up and down as needed as can individual movable pocket components.

FIGS. 4H-4K illustrate the manner in which the tray frame 401, the movable columns 405 and the movable pocket components 407, described above with reference to FIGS. 4B-4G, operate together to make the tray 400 customizable. FIG. 4H shows an assemblage of the movable pocket components 407 and the movable column 405. The movable pocket components 407 includes package support 441. In FIG. 4H the movable pocket component 407 is placed and locked onto the movable magnetic column 405 at a specific location. In an embodiment, the placement position of the movable pocket component 407 is identified/identifiable based on the position of the magnetized interlocking structures of the movable magnetic column 405 to be engaged by the magnetized interlocking structures of the movable pocket component 407. In an embodiment, the position of each of the magnetized interlocking structures is known. Referring to FIG. 4H, movement of the movable pocket component 407 is restricted by the interlocking geometrical patterns of the magnitized interlocking structures 423 in the x direction, the clip 435 in the z direction, and the magnitization of the interlocking structures 423 and 439 in the y direction (direction out of the page).

FIG. 4I is an illustration that shows a perspective view of the assemblage of the movable pocket component 407 and the movable column 405. FIG. 4I shows the movable pocket component clip 435 of movable pocket component 407 inserted into the column track 425. In addition, FIG. 4I shows first fiducial 443 and second fiducial 445 that are used to accurately place the movable pocket component 407 onto the movable column 405. The movable pocket component 407 can be placed and movably locked to any position along the movable column 405 that is desired. In an embodiment, the choice of the placement of the movable modular pocket components 407 can be based on the dimensions of the packages that the tray 400 is being configured to accommodate.

FIG. 4J is an illustration that shows another perspective view of an example assemblage of the movable pocket component 407 and the movable column 405. FIG. 4J shows the movable pocket component 407 positioned with the anterior portion of its base located adjacent the interlocking structures 417 of the tray 400. In addition, FIG. 4J shows column clip fiducial 427 that is used for accurate placement of the movable column 405 and column track fiducials 429 that are used in the placement of the movable pocket component 407. In an embodiment, the movable pocket component 407 is positioned to act as a pocket of a set of pockets that are positioned (e.g., as shown in FIG. 4A) to accommodate a semiconductor package.

FIG. 4K is an illustration that shows another perspective view of the assemblage of the movable pocket component 407 and the column 405. In FIG. 4K, magnetic interlocking structures on the clip side of the movable pocket component 407 are shown as engaging magnetic interlocking structures 423 that are located on the side of the movable column 405. In addition, shown in FIG. 4K is the package support component 441 upon which the package that is accommodated by the pocket component 407 is placed. FIG. 4L shows an example pocket configuration. In the FIG. 4L pocket configuration the pocket components located on the left are clipped to the tracks 403 of the tray 400 (as opposed to being clipped to tracks of a column). The pocket components located on the right are clipped to the tracks 425 of the tray column 405. The position of the pocket components are set to accommodate a package of known dimensions.

Referring again to FIG. 4A, the fully assembled tray 400 with the columns 405 and movable pocket components 407 clipped into place is shown. In FIG. 4A, the arrows indicate that the columns 405 can be indexed left and right and the movable pocket components 407 can be indexed up and down. Because the tray is fully adjustable, it can be adjusted to accommodate other form factors. In contrast, to the standard tray 100 shown in FIG. 3 which is nonadjustable, the tray 400 as shown in the FIG. 4A embodiment, is fully adjustable and can accommodate various form factors and tray densities. In an embodiment, this flexibility is accomplished using tray components that can be assembled in a straightforward manner, can be accurately placed and are reusable.

FIG. 5 is an illustration of a tray such as shown in FIG. 4A reconfigured to accommodate packages of a different size than the packages of FIG. 4A according to an embodiment. In FIG. 5 the dimensions of the packages are different from the dimensions of the packages that are shown in FIG. 4A. Referring to FIG. 5, there is shown three rows of pockets where each of the rows of pockets contains four pockets. As such, twelve packages can be accommodated by a tray configured as shown in FIG. 5. As shown in FIG. 5, the same or similar tray that was previously configured to accommodate a packages having first dimensions can be reconfigured to accommodate packages having other dimensions. In the FIG. 5 embodiment, the reconfiguration of a tray such as tray 400 enables the accommodation of more packages with different dimensions than is accommodated by tray 400 configured as shown in FIG. 4A.

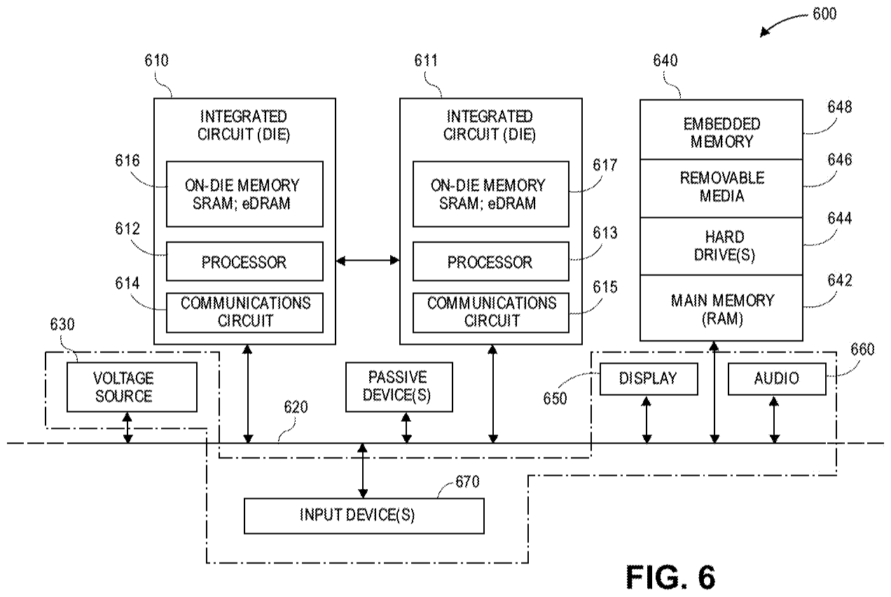

FIG. 6 is a schematic of a computer system 600, in accordance with an embodiment of the present invention. The computer system 600 (also referred to as the electronic system 600) as depicted can embody packages from tray 400, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, packages from tray 400, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having packages from tray 400, according to any of the several disclosed embodiments and their equivalents, an electronic system, a computer system, one or more methods of fabricating an integrated circuit, and one or more methods of fabricating an electronic assembly that includes a package substrate having packages from tray 400, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having packages from tray 400 embodiments and their equivalents. A foundation substrate may be included, as represented by the dashed line of FIG. 6. Passive devices may also be included, as is also depicted in FIG. 6.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

### Example Embodiment 1

An assembly and test tray comprises a tray frame and at least one column movably coupled to the tray frame. At least one pocket component is movably coupled to the column.

### Example Embodiment 2

The assembly and test tray of embodiment 1, wherein the tray frame includes a space that is in the center of the tray frame.

### Example Embodiment 3

The assembly and test tray of embodiment 2, wherein tracks surround the space in the center of the tray frame.

### Example Embodiment 4

The assembly and test tray of embodiment 1, wherein the at least one column includes a clip.

### Example Embodiment 5

The assembly and test tray of embodiment 1, wherein the at least one column includes interlocking structures.

### Example Embodiment 6

The assembly and test tray of embodiment 1, wherein the at least one column includes a clip.

### Example Embodiment 7

The assembly and test tray of embodiment 1, 2, 3, 4, 5 or 6 wherein the at least one pocket component includes a clip.

### Example Embodiment 8

An assembly and test tray comprises a tray frame and a plurality of pockets movably coupled to the tray frame. Each of the plurality of pockets includes a plurality of pocket components.

### Example Embodiment 9

The assembly and test tray of embodiment 8, wherein at least one of the plurality of pockets is movably coupled to the tray frame by a column.

### Example Embodiment 10

The assembly and test tray of embodiment 8, wherein the tray frame includes a space that is in the center of the tray frame.

### Example Embodiment 11

The assembly and test tray of embodiment 10, wherein tracks surround the space in the center of the tray frame.

### Example Embodiment 12

The assembly and test tray of embodiment 9, wherein the column includes a clip.

### Example Embodiment 13

The assembly and test tray of embodiment 9, wherein the column includes interlocking structures.

### Example Embodiment 14

The assembly and test tray of embodiment 9, 10, 11, 12 or 13 wherein each one of the plurality of pockets includes a plurality of pocket components.

### Example Embodiment 15

The assembly and test tray of embodiment 14, wherein each one of the plurality of pocket components includes a clip.

### Example Embodiment 16

An assembly and test tray comprises first interlocking structures on a tray frame and second interlocking structures on at least one column. A portion of the second interlocking structures engage a portion of the first interlocking structures. The assembly and test tray also includes third interlocking structures on at least one pocket component. A portion of the third interlocking structures engage a portion of the second interlocking structures.

### Example Embodiment 17

The assembly and test tray of claim 16, wherein the at least one pocket component is movably coupled to the tray frame by the at least one column.

### Example Embodiment 18

The assembly and test tray of embodiment 16, wherein the tray frame includes a space in the center of the tray frame.

### Example Embodiment 19

The assembly and test tray of embodiment 18, wherein tracks surround the space in the center of the tray frame.

### Example Embodiment 20

The assembly and test tray of embodiment 17, 18 or 19 wherein the at least one column includes a clip.

What is claimed is:

1. An assembly and test tray, comprising:
a tray frame;
at least one column movably coupled to the tray frame; and
at least one pocket component movably coupled to the column.

2. The assembly and test tray of claim 1, wherein the tray frame includes a space that is in the center of the tray frame.

3. The assembly and test tray of claim 2, wherein tracks surround the space in the center of the tray frame.

4. The assembly and test tray of claim 1, wherein the at least one column includes a clip.

5. The assembly and test tray of claim 1, wherein the at least one column includes interlocking structures.

6. The assembly and test tray of claim 1, wherein the at least one column includes a clip.

7. The assembly and test tray of claim 1, wherein the at least one pocket component includes a clip.

8. An assembly and test tray, comprising:
a tray frame; and
a plurality of pockets movably coupled to the tray frame, each of the plurality of pockets including a plurality of pocket components.

9. The assembly and test tray of claim 8, wherein at least one of the plurality of pockets is movably coupled to the tray frame by a column.

10. The assembly and test tray of claim 8, wherein the tray frame includes a space that is in the center of the tray frame.

11. The assembly and test tray of claim 10, wherein tracks surround the space in the center of the tray frame.

12. The assembly and test tray of claim 9, wherein the column includes a clip.

13. The assembly and test tray of claim 9, wherein the column includes interlocking structures.

14. The assembly and test tray of claim 9, wherein each one of the plurality of pockets includes a plurality of pocket components.

15. The assembly and test tray of claim 14, wherein each one of the plurality of pocket components includes a clip.

16. An assembly and test tray, comprising:
first interlocking structures on a tray frame;
second interlocking structures on at least one column, a portion of the second interlocking structures engaging a portion of the first interlocking structures; and
third interlocking structures on at least one pocket component, a portion of the third interlocking structures engaging a portion of the second interlocking structures.

17. The assembly and test tray of claim 16, wherein the at least one pocket component is movably coupled to the tray frame by the at least one column.

18. The assembly and test tray of claim 16, wherein the tray frame includes a space in the center of the tray frame.

19. The assembly and test tray of claim 18, wherein tracks surround the space in the center of the tray frame.

20. The assembly and test tray of claim 17, wherein the at least one column includes a clip.
